(19) United States
(12) Patent Application Publication
(10) Pub. No.: US 2014/0027275 A1
(43) Pub. Date: Jan. 30, 2014

(54) ADAPTER OF SPUTTERING CHAMBER

(71) Applicant: Chia-Chi Kao, Taoyuan County (TW)

(72) Inventor: Chia-Chi Kao, Taoyuan County (TW)

(73) Assignee: UNITED MICROELECTRONICS CORP., Hsinchu (TW)

(21) Appl. No.: 13/560,156

(22) Filed: Jul. 27, 2012

(51) Int. Cl. C23C 14/34

(52) U.S. Cl. 204/298.09

(57) ABSTRACT

The adapter used in the sputtering chamber or the sputtering tool is provided. The adapter body of the adapter has a central hole and at least one cooling channel embedded therein. The cooling channel circulates the adapter body with a fluid flowing therein, and the cooling channel is set surrounding the central hole and is located between a border of the adapter body and the central hole. The adapter having the cooling channel improves the cooling efficiency of the heater as well as the yield of the sputtering chamber.

### BACKGROUND OF THE INVENTION

1. Field of the Invention

The present invention relates to a sputtering tool. More particularly, the present invention relates to an adapter of the sputtering chamber.

2. Description of Related Art

Sputtering has become the most widely used vacuum deposition technique in semiconductor industry. Sputtering in principle involves the ejection of atoms of a target material by energetic ion bombardment. During sputtering, the chamber pressure can influence the quality, uniformity, con-formality, and stress of the resultant film. As the process window of the pressure is quite narrow and usually high vacuum is required, the cryogenic pump (cryo-pump) is incorporated in the sputtering system in order to achieve stable high vacuum.

However, when the sputtering process lasts longer for depositing thicker films, the temperature of the sputtering chamber is increased and the working efficiency of the cryo-pump is diminished, leading to problems like unstable vacuum or even idling of the sputtering system.

### SUMMARY OF THE INVENTION

The present invention related to an adapter fitted to a chamber body of a sputtering chamber, which provides better cooling efficiency and improves the process stability of the sputtering chamber or tool.

The present disclosure provides an adapter having an adapter body with a central hole and a cooling channel embedded therein. The cooling channel circulates the adapter body with a fluid flowing therein. The cooling channel is set surrounding the central hole and is located between a border of the adapter body and the central hole.

The present disclosure also provides a sputtering tool or a sputtering chamber using the above described adapter. The sputtering tool has a chamber lid, a chamber switch, a source mounting plate, a magnet, a target, an adapter, a clamp ring, a heater, a wafer lift and a chamber body. The heater and the wafer lift are located within the accommodating space of the chamber body. The heater and the wafer lift are fixed to the chamber body by the clamp ring. The adapter located on the chamber body has a central hole and a cooling channel embedded therein. The cooling channel circulates the adapter with a fluid flowing therein, and the cooling channel is set surrounding the central hole and is located between a border of the adapter and the central hole. The magnet is fitted into the target and the source mounting plate. The chamber switch and the chamber lid located on the chamber switch are assembled to the chamber body.

As embodied and broadly described herein, the adapter of this invention can has one or more cooling channels to improve the cooling efficiency. The adapter may further have a surface coating over a whole surface thereof. The fluid used in the cooling channel may be de-ionized water. Also, the cross-sectional shape of the cooling channel is circular, oval, rectangular, square, rhomboidal or polygonal, and a ratio of a cross-sectional area of the cooling channel to that of the adapter is 0.02˜0.05. Furthermore, the cooling effect of the adapter can help stabilize the process temperature and improve the product yield.

In order to make the aforementioned and other objects, features and advantages of the present invention comprehensible, embodiments accompanied with figures are described in detail below. It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a sputtering system according to an embodiment of this disclosure.

FIG. 1B is a dismantled view of the deposition chamber of a sputtering system according to an embodiment of this disclosure.

FIG. 1C is an enlarged view of a portion of the assembled deposition chamber according to an embodiment of this disclosure.

FIG. 2A is a three-dimensional view of the adapter according to one embodiment of this disclosure.

FIG. 2B is a top view of the adapter having the cooling channel according to one embodiment of this disclosure.

FIG. 2C is a top dissected view of the adapter with the cooling channels exposed according to another embodiment of this disclosure.

FIGS. 3A-3C are cross-sectional views of cooling channel(s) of the adapter according to embodiments of this disclosure.

FIG. 4A is a graph showing the relationship of the exterior temperature of the adapter versus the processed slot numbers for the design without the cooling channel.

FIG. 4B is a graph showing the relationship of the exterior temperature of the adapter versus the processed slot numbers for the design with the cooling channel.

FIG. 5A is a graph showing the relationship of the total process reaction time of each wafer over the wafer slots for the design without the cooling channel.

FIG. 5B is a graph showing the relationship of the total process reaction time of each wafer over the wafer slots for the design with the cooling channel.

### DESCRIPTION OF EMBODIMENTS

The present invention is described below in detail with reference to the accompanying drawings, and the embodiments of the present invention are shown in the accompanying drawings. However, the present invention can also be implemented in a plurality of different forms, so it should not be interpreted as being limited in the following embodiments. Actually, the following embodiments are intended to demonstrate and illustrate the present invention in a more detailed and completed way, and to fully convey the scope of the present invention to those of ordinary skill in the art. In the accompanying drawings, in order to be specific, the size and relative size of each layer and each region may be exaggeratedly depicted.

It should be known that although “upper”, “lower”, “top”, “bottom”, “under”, “on”, and similar words for indicating the relative space position are used in the present invention to illustrate the relationship between a certain element or feature and another element or feature in the drawings. It should be known that, beside those relative space words for indicating the directions depicted in the drawings, if the element/structure in the drawing is inverted, the element described as “upper” element or feature becomes “lower” element or feature.

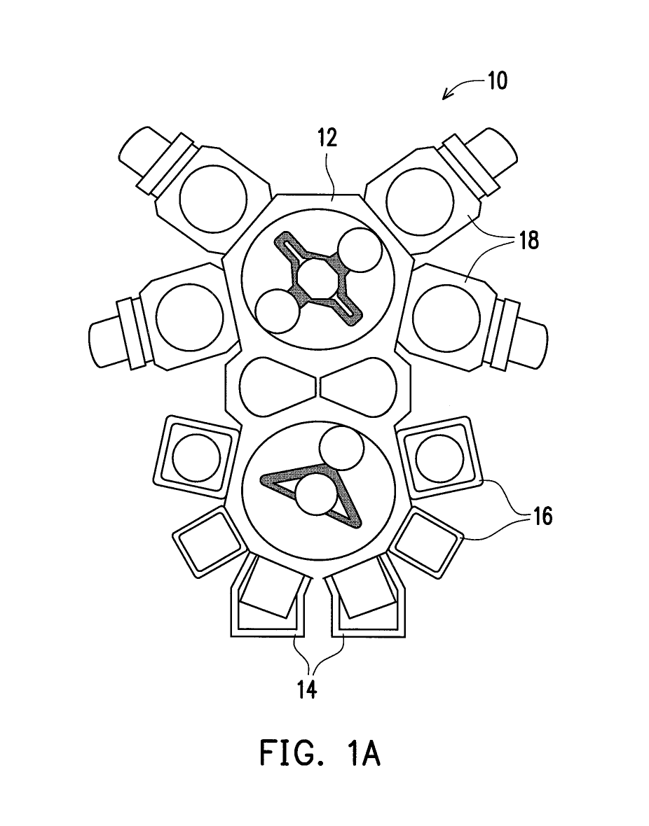

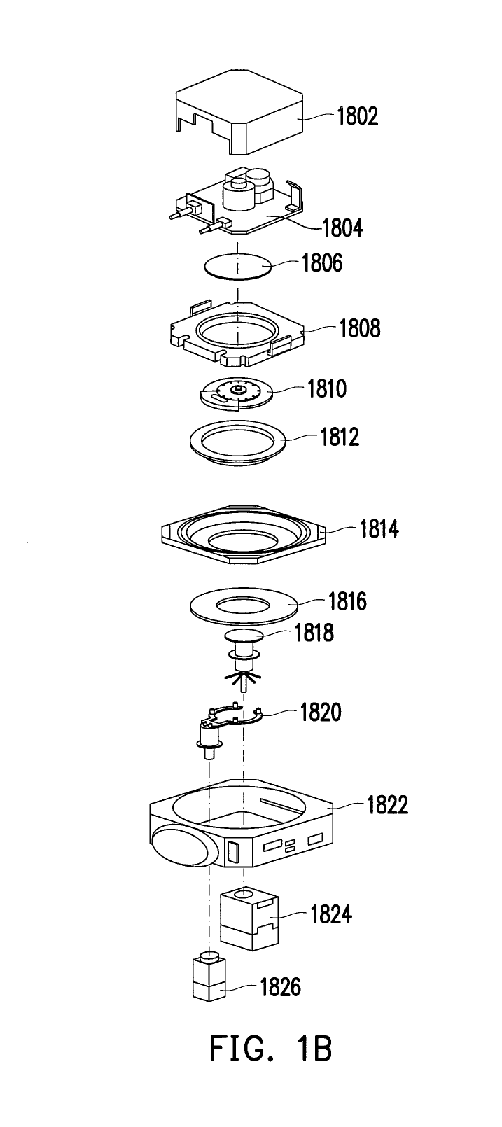

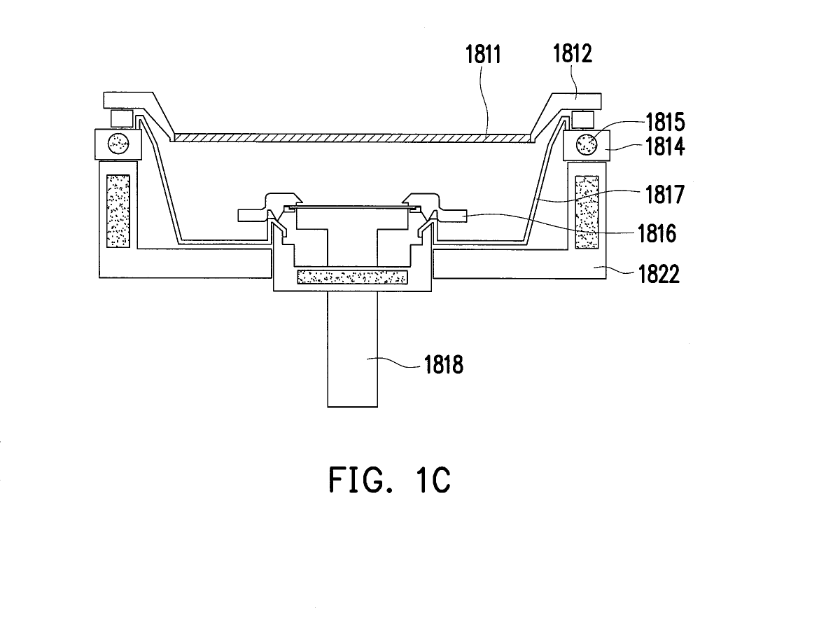

FIG. 1A is a top view of a sputtering system according to an embodiment of this disclosure.

In FIG. 1A, the sputtering system 10 includes a mainframe 12, a cassette load-lock 14, one or more pre-clean or degas chambers 16 and one or more deposition chambers 18 externally mounted on the mainframe 12. The sputtering system 10 may further include electronic control sub-assemblies within the system. The deposition chamber 18 may be a physical vapor deposition (PVD) chamber, for example.

FIG. 1B is a dismantled view of the deposition chamber of a sputtering system according to an embodiment of this disclosure. In FIG. 1B, the chamber 18 includes, sequentially from top to the bottom, a chamber cover 1802, a source assembly 1804, at least one O-ring 1806, a source mounting plate 1808, a magnet 1810, a target 1812, an adapter 1814, a clamp ring 1816, a heater 1818, an upper wafer lift 1820, a chamber body 1822, a heater lift 1824 and a lower wafer lift 1826. The afore-mentioned parts of the chamber 18 are assembled sequentially and stacked together. The chamber body 1822 is a hollow structure having an accommodating space surrounded by four sidewalls. The magnet 1810 is fitted to the source mounting plate 1808 and the source mounting plate 1808 is located on the target 1812. After assembly, the source assembly 1804 and the chamber cover 1802 are fitted and assembled to the chamber body 1822. The connection relationship of the heater 1818 and the heater lift 1824 as well as the upper and lower wafer lifts 1820, 1826 are shown by the dotted lines in FIG. 1B. The heater 1818 also functions as the wafer pedestal to help support the wafer to be sputtered.

FIG. 1C is a partial enlarged view of the assembled deposition chamber according to an embodiment of this disclosure.

In FIG. 1C, as assembled, the heater 1818 and the clamp ring 1816 are located within the accommodating space of the chamber body 1822, and the heater 1818 and the clamp ring 1816 are fixed to the chamber body 1822 by the clamp shield 1817. The adapter 1814 is located right on the chamber body 1822, while the target 1812 is located above the adapter 1814. The target 1812 overlies on top of the adapter 1814 and the adapter 1814 is located directly on the sidewalls of the chamber body 1822. The target 1812 carries the target material 1811 for sputtering.

From FIG. 1C, it is shown that the adapter 1814 includes at least one internal cooling channel or canal 1815 internally circulating around the whole adapter.

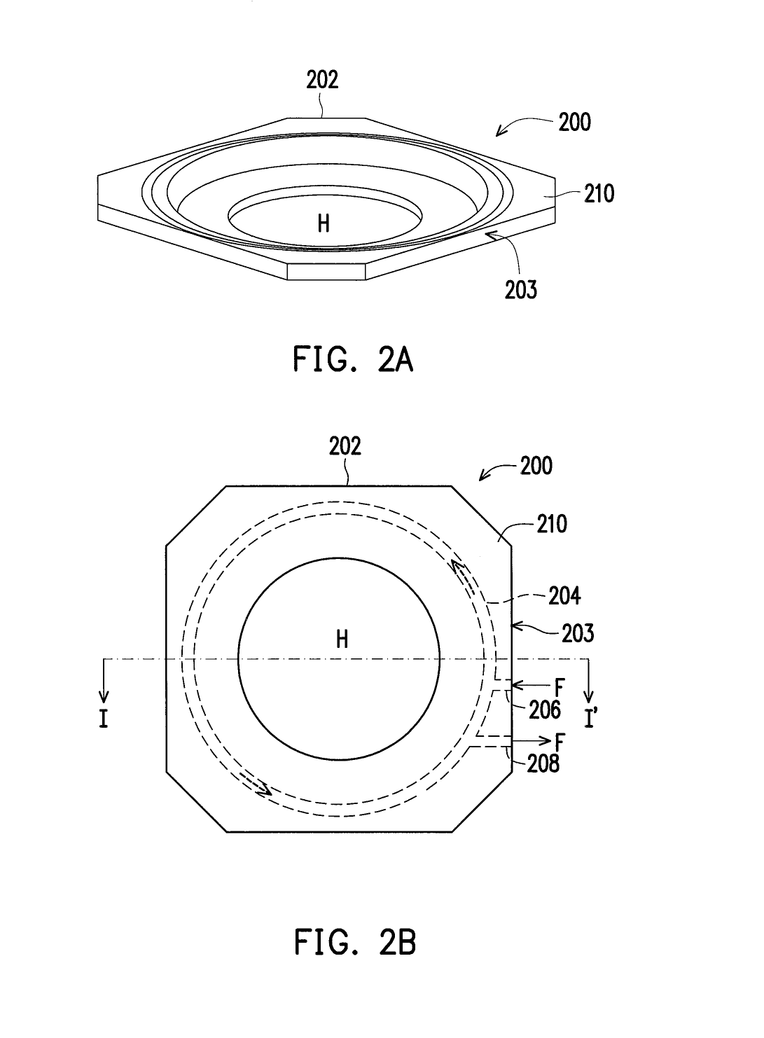

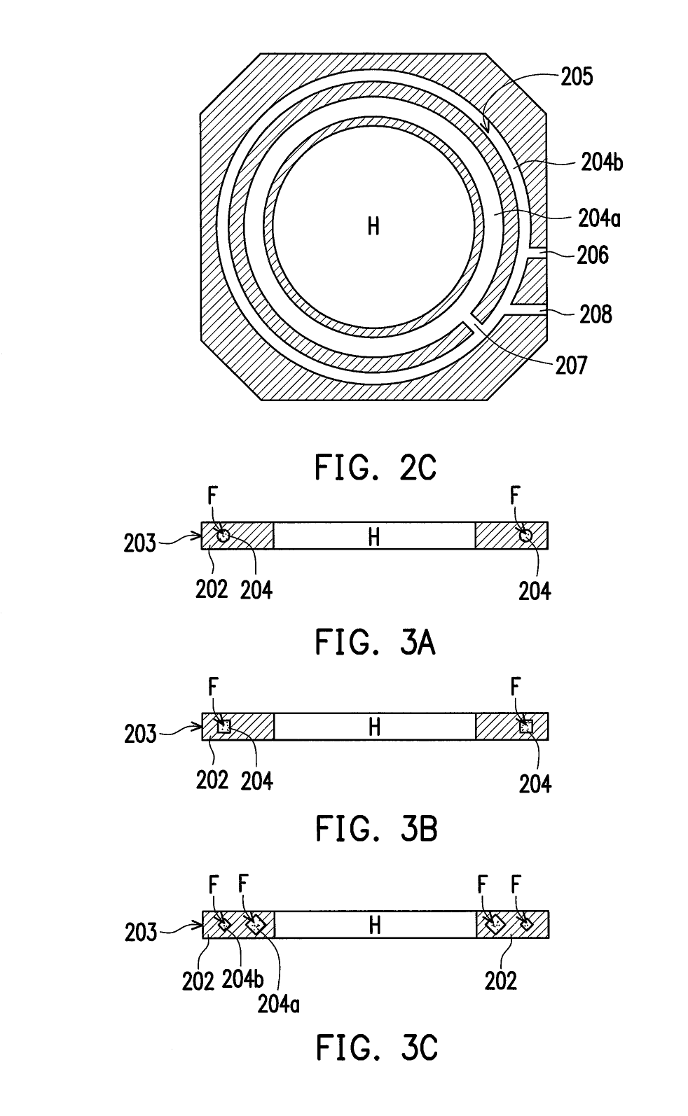

FIGS. 2A and 2B respectively shows a three-dimensional view and a top view of the adapter according to one embodiment of this disclosure. In FIGS. 2A & 2B, the adapter 200 has an adapter body 202, which is a flat frame or ring structure, hollow in the center (having central hole H) and has a border 203 in an octagonal shape. It is understood that the shape or size of the adapter or the adapter body may be modified according to the design of the sputtering tools or the requirements of the sputtering chamber.

Referring to FIGS. 2A & 2B, the adapter body 202 includes at least one cooling channel 204 embedded therein. This hollow cooling channel 204 is completely located inside the adapter body 202 and circulates the adapter body 202 with a fluid F flowing therein. Preferably, the fluid F used in the cooling channel 204 is de-ionized water to provide cooling effects for the heater and the wafer on the heater (FIG. 1B). Supplied from a source (not shown), the fluid F is supplied through the inlet 206, flowing in the cooling channel 204 following the flow direction (shown in arrows) and then departing from the outlet 208 to a recycle tank (not shown). The cooling channel 204 is set within the adapter body 202 as an internal trench surrounding the central hole H of the adapter body 202 and between the central hole H and the border 203.

The adapter body 202 may be made of a metal material, such as aluminum, aluminum alloys, copper or a copper alloy, for example. Also, a surface coating 210, such as anodized aluminum, may be provide over the whole surfaces of the adapter body 202 for protection or anti-oxidation purposes.

FIG. 2C is a top dissected view of the adapter with the cooling channels exposed according to another embodiment of this disclosure. In FIG. 2C, two cooling channels, one inner cooling channel 204a and one outer cooling channel 204b, are provided. The inner cooling channel 204a is located closer to the central hole H, while the outer cooling channel 204b is located closer to the border 203. The cooling channels 204a and 204b may have an inner coating layer 205, such as anodized aluminum, over the inner surface for anti-corrosion purposes. The inner cooling channel 204a and the outer cooling channel 204b may be interlinked by a linking channel 207. Although only one linking channel is shown herein, it is understood that one or several linking channels may be provided for communicating different cooling channels. Similarly, the number of the cooling channels or the relative position of the cooling channels may be adjusted according to requirements of cooling efficiency.

FIGS. 3A-3C are cross-sectional views showing the shapes of the cooling channel(s) of the adapter according to embodiments of this disclosure. FIG. 3A shows the cross-sectional view along the section line I-I′ of FIG. 2B, and the cross-section of the cooling channel 204 is in a circular shape, for example. Alternatively, as shown in FIG. 3B, the cross-section of the cooling channel 204 is in a square shape. The pore size (or diameter) of the cooling channel 204 may be ranging from 3 mm to 10 mm, for example. The relative ratio of the cross-sectional area of the cooling channel 204 to the cross-sectional area of the adapter may be 0.02˜0.05, for example. The cross-sectional shape of the cooling channel may be circular, oval, rectangular, square, rhomboidal or polygonal, for example. For the adapter with two cooling channels (as shown in FIG. 2C), the cross-section of the cooling channels 204a, 204b may be in a rhombus shape. In addition, the inner cooling channel 204a may have a cross-section area larger than that of the outer cooling channel 204b. Depending on the desirable cooling efficiency or product requirements, the cross-sectional shape or the diameter of the cooling channel, the relative ratio of the cross-sectional area between the cooling channel and the adapter may be further customized or adapted.

Owing to the existence of one or more cooling channels in the adapter, the adapter provides better cooling efficiency to itself and to the adjacent heater.

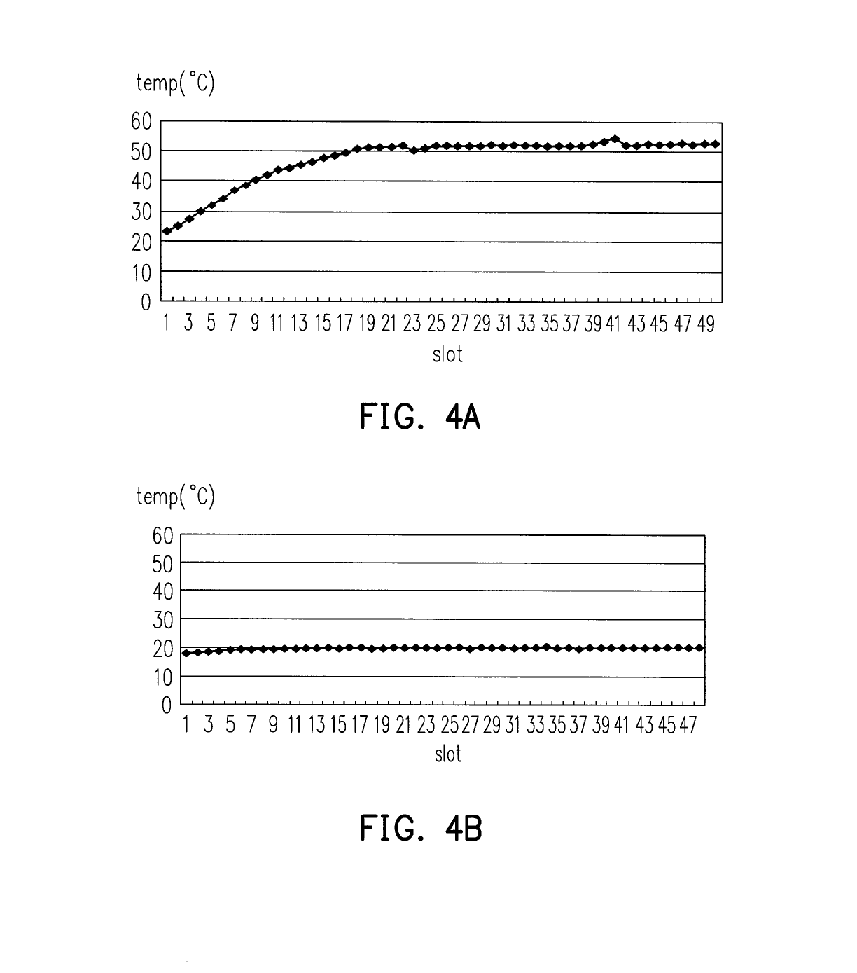

FIG. 4A is a graph showing the relationship of the exterior temperature of the adapter versus the processed slot numbers for the design without the cooling channel, while FIG. 4B is a graph showing the relationship of the exterior temperature of the adapter versus the processed slot numbers for the design with the cooling channel. It is shown that the exterior temperature of the adapter keeps constant at about 20 degrees Celsius over numerous slots. That is, even over lengthy or extended process reaction time, the exterior temperature of the adapter keeps constant, which is beneficial for controlling the heater temperature within the functioning range and preventing the adjacent heater from overheating.

It is verified over experimentation that the temperature of the heater may be raised over the process reaction time but it may reaches a plateau (around 40˜42° C.) and stay in the functioning state (i.e. the functioning range of the heater temperature). On the other hand, for the conventional sputtering tool or chamber, the heater usually becomes out of order when the heater temperature quickly reaches 50° C. Hence, the sputtering tool or the sputtering chamber remains functioning and the undesirable idling or abnormal working state can be avoided.

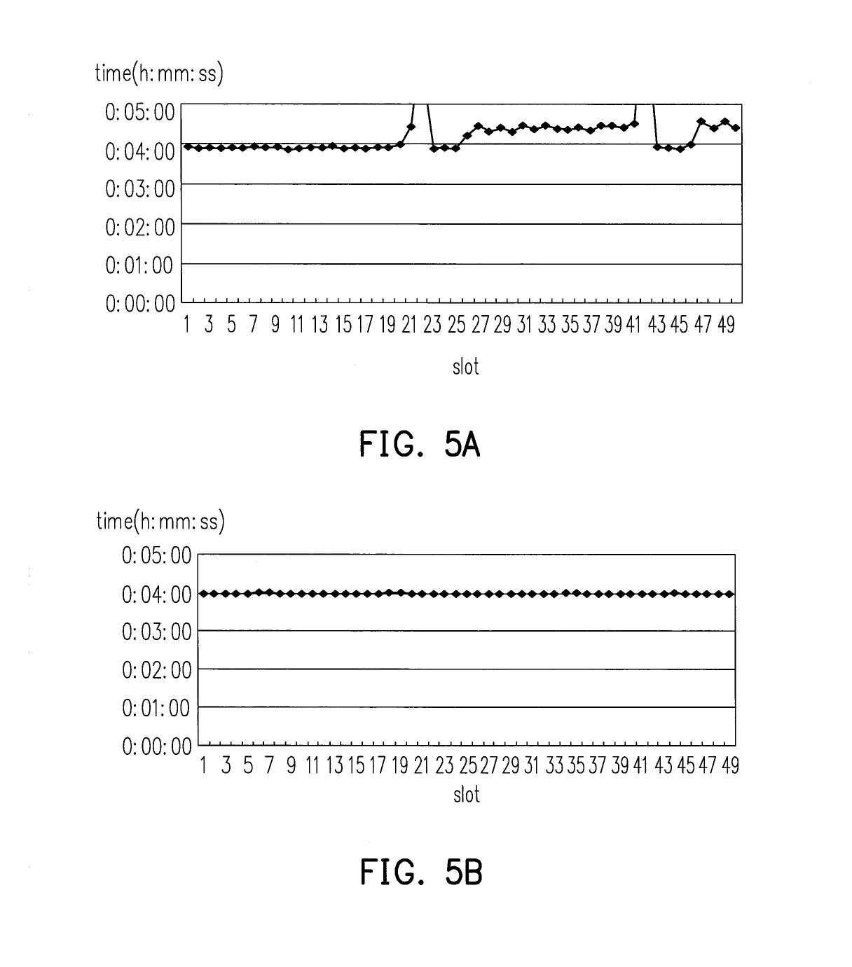

FIG. 5A is a graph showing the relationship of the total process reaction time of each wafer over the wafer slots for the design without the cooling channel, while FIG. 5B is a graph showing the relationship of the total process reaction time of each wafer over the wafer slots for the design with the cooling channel. It is shown that the total process reaction time of each wafer in different slots remains constant, around 4 minutes of total process reaction time for each wafer in the sputtering chamber. This indicates that the sputtering performed to each wafer is consistent and stable.

In conclusion, the cooling efficiency of the sputtering tool or chamber is raised by using for the adapter with one or more cooling channels in this invention. For the sputtering chamber of this invention, the heater temperature remains in the functioning range and the base process time remains constant and stable, due to the better cooling efficiency provided by the adapter around the heater.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An adapter, fitted to a chamber body of a sputtering chamber, comprising:
an adapter body, having a central hole and a cooling channel embedded therein, wherein the cooling channel circulates the adapter body with a fluid flowing therein, and the cooling channel is set surrounding the central hole and is located between a border of the adapter body and the central hole,
wherein adapter body is located under a target and connected to a clamp shield so that a heater is fixed to the chamber body by the clamp shield.

2. The adapter of claim 1, further comprising a surface coating over a whole surface of the adapter.

3. The adapter of claim 1, wherein the fluid used in the cooling channel is de-ionized water.

4. The adapter of claim 1, wherein the cooling channel includes an inlet and an outlet, and the fluid is supplied through the inlet, flowing in the cooling channel and then departing from the outlet.

5. The adapter of claim 1, wherein a cross-sectional shape of the cooling channel is circular, oval, rectangular, square, rhomboidal or polygonal.

6. The adapter of claim 1, wherein a ratio of a cross-sectional area of the cooling channel to that of the adapter ranges from about 0.02 to about 0.05.

7. The adapter of claim 1, further comprising an inner cooling channel embedded within the adapter body and located between the cooling channel and the central hole of the adapter body, wherein the inner cooling channel circulates the adapter body with the fluid flowing therein.

8. The adapter of claim 7, further comprising a linking channel located between the inner cooling channel and the cooling channel to communicate the fluid flowing therein.

9. The adapter of claim 7, wherein a cross-sectional area of the inner cooling channel is larger than that of the cooling channel.

10. The adapter of claim 1, wherein a material of the adapter body includes copper.

11. A sputtering tool, comprising:
a chamber body;
a heater, located within an accommodating space of the chamber body;
a wafer lift, located within the accommodating space of the chamber body, wherein the heater and the wafer lift are fixed to the chamber body by a clamp ring;
an adapter, located on the chamber body, wherein the adapter has a central hole and a cooling channel embedded therein, wherein the cooling channel circulates the adapter with a fluid flowing therein, and the cooling channel is set surrounding the central hole and is located between a border of the adapter and the central hole;
a clamp shield, connected to the adapter, wherein the adapter is connected to the clamp shield so that the heater is fixed to the chamber body by the clamp shield;
a target, located on the adapter;
a source mounting plate, located on the target;
a magnet, fitted into the target and the source mounting plate;
a chamber switch, located above the source mounting plate; and
a chamber lid, located on the chamber switch, above the source mounting plate, the target and the adapter and assembled to the chamber body.

12. The sputtering tool of claim 11, wherein the fluid used in the cooling channel is de-ionized water.

13. The sputtering tool of claim 11, wherein a cross-sectional shape of the cooling channel is circular, oval, rectangular, square, rhomboidal or polygonal.

14. The sputtering tool of claim 11, wherein a ratio of a cross-sectional area of the cooling channel to that of the adapter ranges from about 0.02 to about 0.05.

15. The sputtering tool of claim 11, further comprising an inner cooling channel embedded within the adapter and located between the cooling channel and the central hole of the adapter, wherein the inner cooling channel circulates the adapter with the fluid flowing therein.

16. The sputtering tool of claim 15, further comprising a linking channel located between the inner cooling channel and the cooling channel to communicate the fluid flowing therein.

17. The sputtering tool of claim 15, wherein a cross-sectional area of the inner cooling channel is larger than that of the cooling channel.
